(19) United States
(12) Patent Application Publication
(10) Pub. No.: US 2018/0122289 A1
(43) Pub. Date: May 3, 2018

(54) SHIFT REGISTER, DRIVING METHOD, GATE DRIVING CIRCUIT AND DISPLAY DEVICE

(71) Applicants: BOE TECHNOLOGY GROUP CO., LTD., Beijing (CN); HEFEI BOE OPTOELECTRONICS TECHNOLOGY CO., LTD., Hefie (CN)

(72) Inventors: Honggang Gu, Beijing (CN); Xianjie Shao, Beijing (CN); Jie Song, Beijing (CN)

(21) Appl. No.: 15/678,067

(22) Filed: Aug. 15, 2017

(30) Foreign Application Priority Data
Oct. 27, 2016 (CN) 201610955495.2

(51) Int. Cl. G09G 3/20; G11C 19/28

(52) U.S. Cl. CPC G09G 3/2092; G11C 19/28; G09G 2310/08; G09G 2330/023; G09G 2300/0426; G09G 2330/08; G09G 2310/0286

(57) ABSTRACT

Embodiments of the present disclosure provide a shift register, a driving method, a gate driving circuit and a display device. The shift register comprises a charging circuitry, a reset circuitry, a pull-up circuitry, a pull-down circuitry, a noise reduction circuitry and a pre-reset circuitry, wherein the pre-reset circuitry is coupled to a frame start signal terminal, a third power supply signal terminal, a pull-up node and an output terminal respectively for resetting the pull-up node and the output terminal under control of a frame start signal.

### CROSS-REFERENCE TO RELATED APPLICATION(S)

This application claims priority to a Chinese application No. CN201610955495.2, filed on Oct. 27, 2016, which is incorporated herein by reference in its entirety.

### TECHNICAL FIELD

The present disclosure relates to display technology, and more particularly, to a shift register, a driving method, a gate driving circuit and a display device.

### BACKGROUND

When a display device is displaying an image, it needs to scan pixel cells using a shift register (i.e., a gate driving circuit). The shift register comprises a plurality of shift registers, each shift register corresponding to a row of pixel cells. Respective rows of pixel cells in a display panel are driven in progressive scanning by the plurality of shift registers to display the image.

When there is a chaos timing signal in the shift register, it will cause respective stages of shift registers to be sequentially turned on in error. When a last stage of shift register drives a last row of pixel cells of the display panel to be lit, the last row of pixel cells of the display panel will be always in a lighting state since there is no reset signal for controlling the last stage of shift register to be reset. Therefore, a white line is prone to be badly rendered at a bottom of the display panel.

### SUMMARY

Embodiments of the present disclosure provide a shift register, a driving method, a gate driving circuit and a display device.

According to a first aspect of an embodiment of the present disclosure, a shift register is provided, comprising:

a charging circuitry coupled to an input signal terminal, a first power supply signal terminal and a pull-up node, for charging the pull-up node under control of an input signal from the input signal terminal;

a reset circuitry coupled to a reset signal terminal, a second power supply signal terminal and the pull-up node, for resetting a potential of the pull-up node under control of a reset signal from the reset signal terminal;

a pull-up circuitry coupled to a first clock signal terminal, the pull-up node and an output terminal respectively, for outputting a driving signal to the output terminal under control of the pull-up node;

a pull-down circuitry coupled to the pull-up node, a pull-down node, a third power supply signal terminal and a second clock signal terminal, for controlling a potential of the pull-down node under control of the pull-up node and a second clock signal from the second clock signal terminal;

a noise reduction circuitry coupled to the pull-down node, the third power supply signal terminal, the pull-up node and the output terminal, for performing noise reduction on the pull-up node and the output terminal under control of the pull-down node; and

a pre-reset circuitry coupled to a frame start signal terminal, the third power supply signal terminal, the pull-up node and the output terminal, for resetting the potential of the pull node and a potential of the output terminal under control of a frame start signal from the frame start signal terminal.

For example, the pre-reset circuitry comprises a first transistor and a second transistor; a gate of the first transistor is coupled to the frame start signal terminal, a first electrode of the first transistor is coupled to the third power supply signal terminal, and a second electrode of the first transistor is coupled to the pull-up node; and a gate of the second transistor is coupled to the frame start signal terminal, a first electrode of the second transistor is coupled to the third power supply signal terminal, and a second electrode of the second transistor is coupled to the output terminal.

For example, the pre-reset circuitry comprises a third transistor, a fourth transistor and a fifth transistor; a gate and a first electrode of the third transistor are coupled to the frame start signal terminal, and a second electrode of the third transistor is coupled to the pull-down node; a gate of the fourth transistor is coupled to the pull-down node, a first electrode of the fourth transistor is coupled to the third power supply signal terminal, and a second electrode of the fourth transistor is coupled to the output terminal; and a gate of the fifth transistor is coupled to the pull-down node, a first electrode of the fifth transistor is coupled to the third power supply signal terminal, and a second electrode of the fifth transistor is coupled to the pull-up node.

For example, the pull-down circuitry comprises a sixth transistor, a seventh transistor and a first capacitor; a gate of the sixth transistor is coupled to the pull-up node, a first electrode of the sixth transistor is coupled to the third power supply signal terminal, and a second electrode of the sixth transistor is coupled to the pull-down node; a gate and a first electrode of the seventh transistor are coupled to the second clock signal terminal, and a second electrode of the seventh transistor is coupled to the pull-down node; and one terminal of the first capacitor is coupled to the pull-down node, and the other terminal of the first capacitor is coupled to the third power supply signal terminal.

For example, the charging circuitry comprises an eighth transistor, and the reset circuitry comprises a ninth transistor, wherein when forward scanning is being performed, a gate of the eighth transistor is coupled to the input signal terminal, a first electrode of the eighth transistor is coupled to the first power supply signal terminal, and a second electrode of the eighth transistor is coupled to the pull-up node; a gate of the ninth transistor is coupled to the reset signal terminal, a first electrode of the ninth transistor is coupled to the second power supply signal terminal, and a second electrode of the ninth transistor is coupled to the pull-up node.

For example, the charging circuitry comprises a ninth transistor, and the reset circuitry comprises an eighth transistor; when backward scanning is being performed, a gate of the ninth transistor is coupled to the input signal terminal, a first electrode of the ninth transistor is coupled to the first power supply signal terminal, and a second electrode of the ninth transistor is coupled to the pull-up node; and a gate of the eighth transistor is coupled to the reset signal terminal, a first electrode of the eighth transistor is coupled to the second power supply signal terminal, and a second electrode of the eighth transistor is coupled to the pull-up node.

For example, the pull-up circuitry comprises a tenth transistor and a second capacitor; and the noise reduction circuitry comprises an eleventh transistor and a twelfth transistor; a gate of the tenth transistor is coupled to the pull-up node, a first electrode of the tenth transistor is coupled to the first clock signal terminal, and a second electrode of the tenth transistor is coupled to the output terminal; one terminal of the second capacitor is coupled to the pull-up node, and the other terminal of the second capacitor is coupled to the output terminal; a gate of the eleventh transistor is coupled to the pull-down node, a first electrode of the eleventh transistor is coupled to the third power supply signal terminal, and a second electrode of the eleventh transistor is coupled to the output terminal; and a gate of the twelfth transistor is coupled to the pull-down node, a first electrode of the twelfth transistor is coupled to the third power supply signal terminal, and a second electrode of the twelfth transistor is coupled to the pull-up node.

For example, the noise reduction circuitry comprises the fourth transistor and the fifth transistor.

For example, each of the transistors is an N-type transistor.

According to a second aspect of an embodiment of the present disclosure, a driving method of a shift register is provided, wherein the shift register comprises a charging circuitry, a reset circuitry, a pull-up circuitry, a pull-down circuitry, a noise reduction circuitry and a pre-reset circuitry, the driving method comprising:

in a pre-reset period, outputting, by the pre-reset circuitry, a third power supply signal to the pull-up node and the output terminal respectively under control of a frame start signal;

in a charging period, outputting, by the charging circuitry, a first power supply signal to the pull-up node under control of an input signal;

in an outputting period, maintaining, by the pull-up node, a potential of the first power supply signal; and outputting, by the pull-up circuitry, a first clock signal to the output terminal under control of the pull-up node;

in a reset period, outputting, by the reset circuitry, a second power supply signal to the pull-up node under control of a reset signal; outputting, by the pull-down circuitry, a second clock signal to the pull-down node under control of the second clock signal; and outputting, by the noise reduction circuitry, the third power supply signal to the pull-up node and the output terminal respectively under control of the pull-down node; and

in a noise reduction period, maintaining, by the pull-down node, a potential of the second clock signal; and outputting, by the noise reduction circuitry, the third power supply signal to the pull-up node and the output terminal respectively under the control of the pull-down node.

For example, the pre-reset circuitry comprises a first transistor and a second transistor; and the method further comprises in the pre-reset period, turning on the first transistor and the second transistor, outputting by the third power supply signal terminal, s the third power supply signal to the pull-up node and the output terminal respectively, and the frame start signal is at a first potential, and a potential of the third power supply signal is a second potential.

For example, the pre-reset circuitry comprises a third transistor, a fourth transistor and a fifth transistor; and the method further comprises in the pre-reset period, turning on the third transistor, outputting by a frame start signal terminal, the frame start signal to the pull-down node, turning on the fourth transistor and the fifth transistor, outputting by the third power supply signal terminal, the third power supply signal to the pull-up node and the output terminal respectively, and a potential of the third power supply signal is a second potential, and the frame start signal is at a first potential.

For example, the pull-down circuitry comprises a sixth transistor, a seventh transistor and a first capacitor; the method further comprises in the charging period and the outputting period, turning on the sixth transistor, outputting by the third power supply signal terminal, the third power supply signal to the pull-down node, and a potential of the third power supply signal is a second potential and a potential of the pull-up node is a first potential;

in the reset period, turning on the seventh transistor, and outputting by the second clock signal terminal, the second clock signal to the pull-down node for charging the first capacitor, and the second clock signal is at the first potential; and

in the noise reduction period, causing by the first capacitor, the pull-down node to maintain at a first potential.

For example, each of the transistors is an N-type transistor, and the first potential is a high potential relative to the second potential.

According to a third aspect of an embodiment of the present disclosure, a gate driving circuit is provided, the gate driving circuit comprising at least two cascaded shift registers according to the embodiments of the present disclosure.

According to a fourth aspect of an embodiment of the present disclosure, a display device is provided, comprising the gate driving circuit according to the embodiments of the present disclosure.

### BRIEF DESCRIPTION OF THE DRAWINGS

In order to more clearly illustrate the technical solution in the embodiments of the present invention, the following drawings, which are intended to be used in the description of the embodiments, will be briefly described. It will be apparent that the drawings in the following description are merely examples of the present disclosure. Other drawings of the art may be obtained by those skilled in the art without departing from the inventive work.

FIG. 1 shows a schematic structure diagram of a shift register according to an embodiment of the present disclosure;

FIG. 2 shows another schematic structure diagram of a shift register according to an embodiment of the present disclosure;

FIG. 3 shows another schematic structure diagram of a shift register according to an embodiment of the present disclosure;

FIG. 4 shows another schematic structure diagram of a shift register according to an embodiment of the present disclosure;

FIG. 5 shows another schematic structure diagram of a shift register according to an embodiment of the present disclosure;

FIG. 6 shows a flowchart of a driving method of a shift register according to an embodiment of the present disclosure;

FIG. 7 shows a timing sequence diagram of a driving process of a shift register according to an embodiment of the present disclosure; and

FIG. 8 shows a schematic structure diagram of a gate driving circuit according to an embodiment of the present disclosure.

### DETAILED DESCRIPTION

In order to further clarify objects, advantages and advantages of embodiments of the present disclosure, the embodiments of the present disclosure will be further described in detail with reference to the accompanying drawings.

Transistors used in all embodiments of the present disclosure may be thin film transistors or field effect transistors or other devices having the same characteristics. According to their functions in a circuit, the transistors used in the embodiments of the present disclosure are mainly switch transistors. Since a source and a drain of the switch transistor used herein are symmetrical, the source and the drain of the switch transistor are interchangeable. In the embodiments of the present disclosure, in order to distinguish two electrodes other than a gate of the transistor, one of the source and the drain is referred to as a first electrode, and the other is referred to as a second electrode. Therefore, the gate of the transistor may also be referred to as a third electrode. A control terminal of the transistor is the gate, a signal input terminal is the source, and a signal output terminal is the drain. All of the switch transistors used in the embodiments of the present disclosure may be N-type switch transistors, the N-type switching transistor being turned on when the gate is at a high potential and being turned off when the gate is at a low potential. In addition, according to the embodiments of the present disclosure, a first potential and a second potential just represent two states of a potential of a signal, but do not represent that the first potential or the second potential has a specific value.

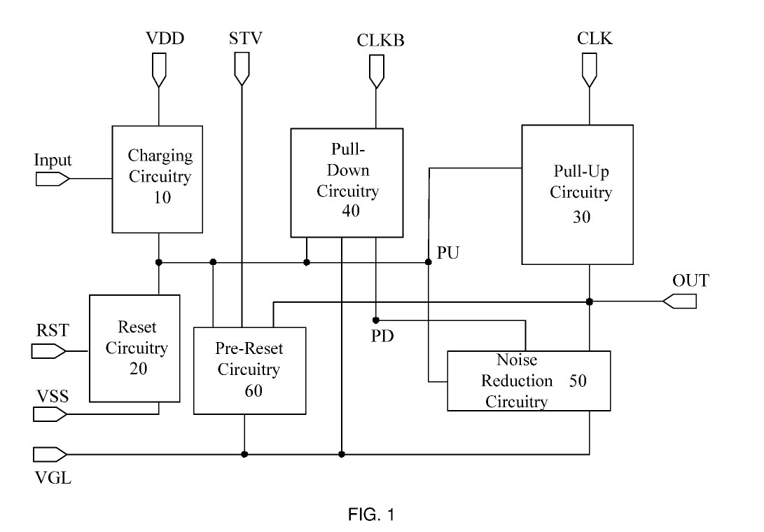

FIG. 1 shows a schematic structure diagram of a shift register according to an embodiment of the present disclosure. With reference to FIG. 1, the shift register may comprise a charging circuitry 10, a reset circuitry 20, a pull-up circuitry 30, a pull-down circuitry 40, a noise reduction circuitry 50 and a pre-reset circuitry 60.

The charging circuitry 10 is coupled to an input signal terminal Input, a first power supply signal terminal VDD and a pull-up node PU, for charging the pull-up node PU under control of an input signal from the input signal terminal Input.

The reset circuitry 10 is coupled to a reset signal terminal RST, a second power supply signal terminal VSS and the pull-up node PU, for resetting a potential of the pull-up node PU under control of a reset signal from the reset signal terminal RST.

The pull-up circuitry 30 is coupled to a first clock signal terminal CLK, the pull-up node PU and an output terminal OUT respectively, for outputting a driving signal to the output terminal OUT under control of the pull-up node PU.

The pull-down circuitry 40 is coupled to the pull-up node PU, a pull-down node PD, a third power supply signal terminal VGL and a second clock signal terminal CLKB, for controlling a potential of the pull-down node PD under control of the pull-up node PU and a second clock signal from the second clock signal terminal CLKB.

The noise reduction circuitry 50 is coupled to the pull-down node PD, the third power supply signal terminal VGL, the pull-up node PU and the output terminal OUT, for performing noise reduction on the pull-up node PU and the output terminal OUT under control of the pull-down node PD.

The pre-reset circuitry 60 is coupled to a frame start signal terminal STV, the third power supply signal terminal VGL, the pull-up node PU and the output terminal OUT, for resetting the potential of the pull node PU and a potential of the output terminal OUT under control of a frame start signal from the frame start signal terminal STV.

It should be noted that in the embodiment of the present disclosure, the frame start signal terminal STV is a signal terminal coupled to an input terminal Input of a first stage of shift register in a gate driving circuit.

In view of the foregoing, the embodiment of the present disclosure provides the shift register, which further comprises the pre-reset circuitry coupled to the frame start signal terminal. Therefore, every time the shift register starts scanning one frame of image, the pre-reset circuitry in each shift register is able to reset the potentials of the pull-up node and the output terminal of the shift register under the control of the frame start signal. Therefore, the shift register which is turned on in error may be turned off in time, so as to avoid a white line being badly rendered at a bottom of a display panel due to an erroneous turn-on of a last stage of shift register, thus improving output stability of the shift register and guaranteeing display effect of the display device.

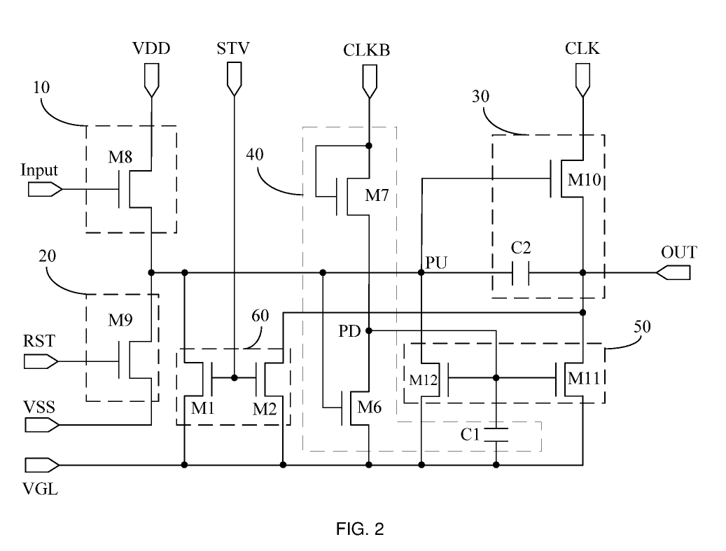

In an implementation of the embodiment of the present disclosure, the pre-reset circuitry 60 may comprise a first transistor M1 and a second transistor M2, with reference to FIG. 2.

A gate of the first transistor M1 is coupled to the frame start signal terminal STV, a first electrode of the first transistor M1 is coupled to the third power supply signal terminal VGL, and a second electrode of the first transistor M1 is coupled to the pull-up node PU.

A gate of the second transistor M2 is coupled to the frame start signal terminal STV, a first electrode of the second transistor M2 is coupled to the third power supply signal terminal VGL, and a second electrode of the second transistor M2 is coupled to the output terminal OUT.

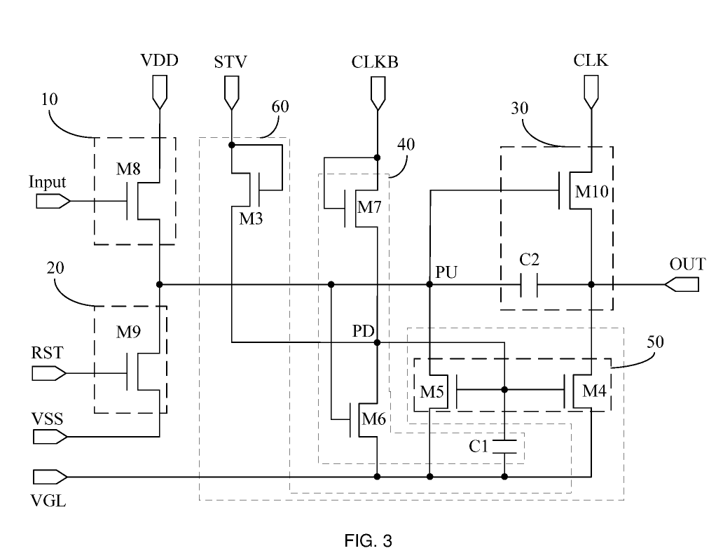

In another implementation of the embodiment of the present disclosure, the pre-reset circuitry 60 may comprise a third transistor M3, a fourth transistor M4 and a fifth transistor M5, with reference to FIG. 3.

A gate and a first electrode of the third transistor M3 are coupled to the frame start signal terminal STV, and a second electrode of the third transistor M3 is coupled to the pull-down node PD.

A gate of the fourth transistor M4 is coupled to the pull-down node PD, a first electrode of the fourth transistor M4 is coupled to the third power supply signal terminal VGL, and a second electrode of the fourth transistor M4 is coupled to the output terminal OUT.

A gate of the fifth transistor M5 is coupled to the pull-down node PD, a first electrode of the fifth transistor M5 is coupled to the third power supply signal terminal VGL, and a second electrode of the fifth transistor M5 is coupled to the pull-up node PU.

Further, with reference to FIG. 2 and FIG. 3, the pull-down circuitry 40 may comprise a sixth transistor M6, a seventh transistor M7 and a first capacitor C1. A gate of the sixth transistor M6 is coupled to the pull-up node PU, a first electrode of the sixth transistor M6 is coupled to the third power supply signal terminal VGL, and a second electrode of the sixth transistor M6 is coupled to the pull-down node PD.

A gate and a first electrode of the seventh transistor M7 are coupled to the second clock signal terminal CLKB, and a second electrode of the seventh transistor M7 is coupled to the pull-down node PD.

One terminal of the first capacitor C1 is coupled to the pull-down node PD, and the other terminal of the first capacitor C1 is coupled to the third power supply signal terminal VGL.

The shift register in the embodiment of the present disclosure may perform forward scanning and backward scanning on respective rows of pixel cells in the display device.

When the forward scanning is being performed, as shown in FIG. 2 and FIG. 3, an eighth transistor M8 is comprised in the charging circuitry 10, and a ninth transistor M9 is comprised in the reset circuitry 20. A gate of the eighth transistor M8 is coupled to the input signal terminal Input, a first electrode of the eighth transistor M8 is coupled to the first power supply signal terminal VDD, and a second electrode of the eighth transistor M8 is coupled to the pull-up node PU. A gate of the ninth transistor M9 is coupled to the reset signal terminal RST, a first electrode of the ninth transistor M9 is coupled to the second power supply signal terminal VSS, and a second electrode of the ninth transistor M9 is coupled to the pull-up node PU.

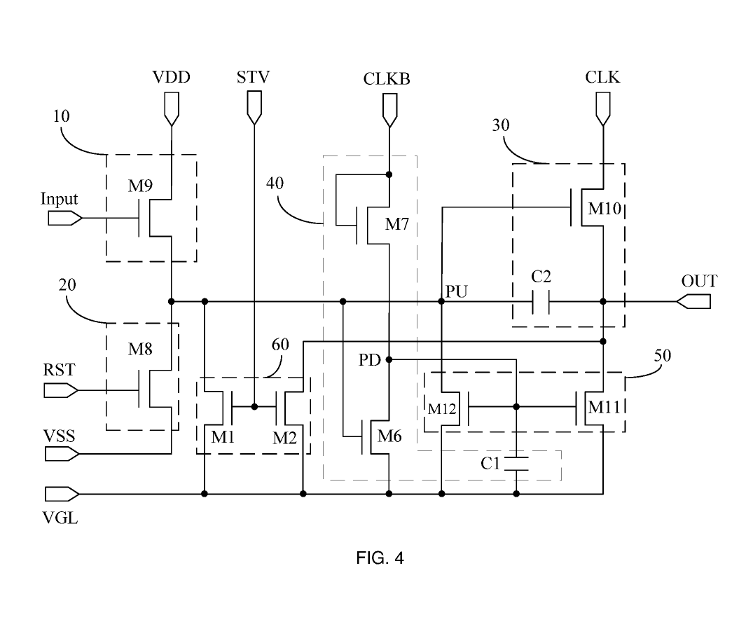

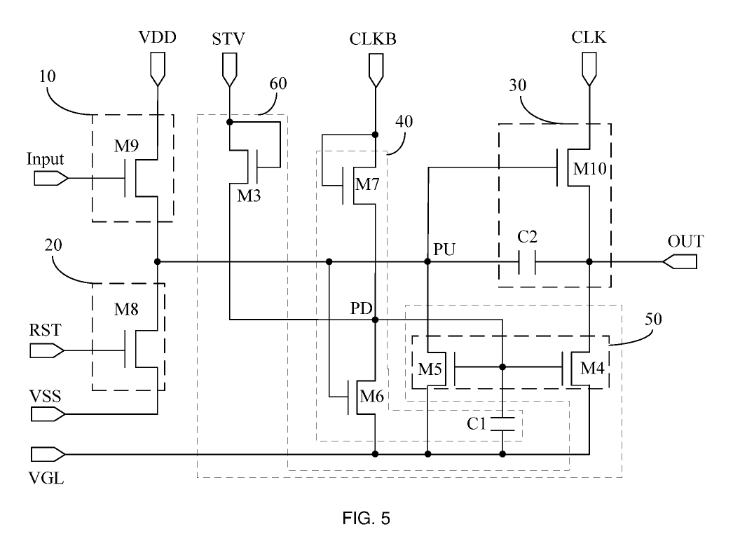

When the backward scanning is being performed, as shown in FIG. 4 and FIG. 5, a ninth transistor M9 is comprised in the charging circuitry 10, and an eighth transistor M8 is comprised in the reset circuitry 20. A gate of the ninth transistor M9 is coupled to the input signal terminal Input, a first electrode of the ninth transistor M9 is coupled to the first power supply signal terminal VDD, and a second electrode of the ninth transistor M9 is coupled to the pull-up node PU. A gate of the eighth transistor M8 is coupled to the reset signal terminal RST, a first electrode of the eighth transistor M8 is coupled to the second power supply signal terminal VSS, and a second electrode of the eighth transistor M8 is coupled to the pull-up node PU.

For example, with reference to FIG. 2 to FIG. 5, the pull-up circuitry 30 may comprise a tenth transistor M10 and a second capacitor C2. A gate of the tenth transistor M10 is coupled to the pull-up node PU, a first electrode of the tenth transistor M10 is coupled to the first clock signal terminal CLK, and a second electrode of the tenth transistor M10 is coupled to the output terminal OUT. One terminal of the second capacitor C2 is coupled to the pull-up node PU, and the other terminal of the second capacitor C2 is coupled to the output terminal OUT.

In an implementation of the embodiment of the present disclosure, with reference to FIG. 2 and FIG. 4, the noise reduction circuitry 50 may comprise an eleventh transistor M11 and a twelfth transistor M12. A gate of the eleventh transistor M11 is coupled to the pull-down node PD, a first electrode of the eleventh transistor M11 is coupled to the third power supply signal terminal VGL, and a second electrode of the eleventh transistor M11 is coupled to the output terminal OUT. A gate of the twelfth transistor M12 is coupled to the pull-down node PD, a first electrode of the twelfth transistor M12 is coupled to the third power supply signal terminal VGL, and a second electrode of the twelfth transistor M12 is coupled to the pull-up node PU.

In another implementation of the embodiment of the present disclosure, with reference to FIG. 3 and FIG. 5, the noise reduction circuitry 50 may comprise the fourth transistor M4 and the fifth transistor M5. That is, the noise reduction circuitry 50 and the pre-reset circuitry 60 may share the fourth transistor M4 and the fifth transistor M5.

Of course, in the shift register as shown in FIG. 3 and FIG. 5, the fourth transistor M4 and the fifth transistor M5 may only belong to the pre-reset circuitry 60. Accordingly, two transistors M11 and M12 may be separately arranged in the noise reduction circuitry 50. Connections between the two transistors M11 and M12 may refer to FIG. 2 and FIG. 4, description of which will be omitted here for simplicity.

According to the embodiment of the present disclosure, the shift register further comprises the pre-reset circuitry coupled to the frame start signal terminal. Therefore, every time the shift register starts scanning one frame of image, the pre-reset circuitry in each shift register is able to reset the pull-up node and the output terminal of the shift register under the control of the frame start signal, so that the shift register which is turned on in error may be turned off in time, in order to avoid the white line being badly rendered at the bottom of the display panel due to the erroneous turn-on of the last stage of shift register, thus improving the output stability of the shift register and guaranteeing the display effect of the display device. In addition, the shift register according to the embodiment of the present disclosure uses fewer components, and occupies less space, which may effectively reduce borders of the display device, and realize a narrow frame design for the display device.

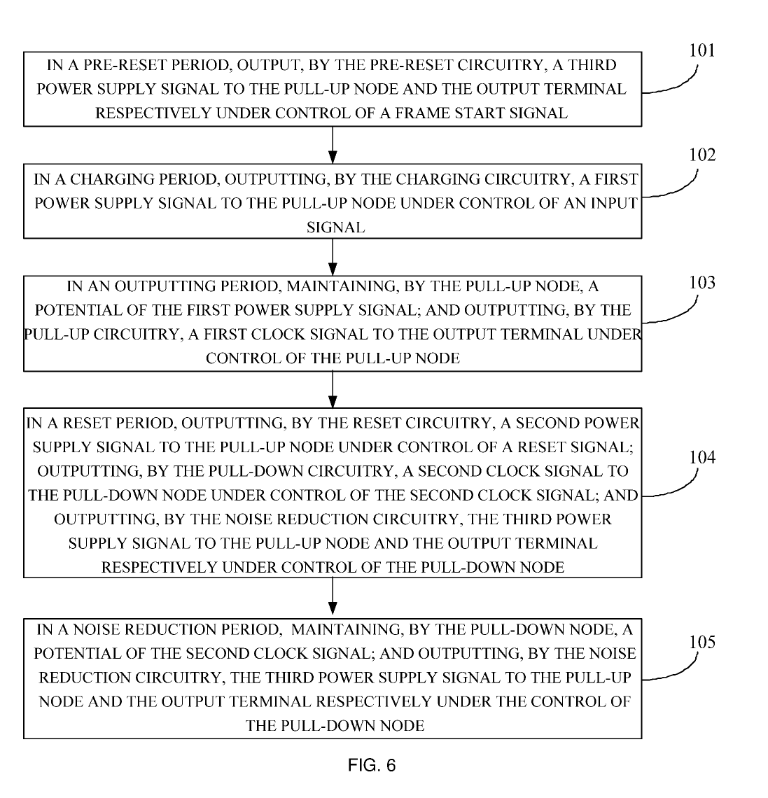

FIG. 6 shows a flowchart of a driving method of a shift register according to an embodiment of the present disclosure. The driving method may be applied to drive the shift register as described with reference to any of FIG. 1 to FIG. 5. As shown in FIG. 1, the shift register may comprise a charging circuitry 10, a reset circuitry 20, a pull-up circuitry 30, a pull-down circuitry 40, a noise reduction circuitry 50 and a pre-reset circuitry 60. With reference to FIG. 6, the driving method may comprise following steps.

In a pre-reset period of step 101, the pre-reset circuitry 60 outputs a third power supply signal to the pull-up node PU and the output terminal OUT respectively under control of a frame start signal.

In a charging period of step 102, the charging circuitry 10 outputs a first power supply signal to the pull-up node PU under control of an input signal.

In an outputting period of step 103, the pull-up node PU maintains a potential of the first power supply signal; and the pull-up circuitry 30 outputs a first clock signal to the output terminal OUT under control of the pull-up node PU.

In a reset period of step 104, the reset circuitry 20 outputs a second power supply signal to the pull-up node PU under control of a reset signal; the pull-down circuitry 40 outputs a second clock signal to the pull-down node PD under control of the second clock signal; and the noise reduction circuitry 50 outputs the third power supply signal to the pull-up node PU and the output terminal OUT respectively under control of the pull-down node PD.

In a noise reduction period of step 105, the pull-down node maintains a potential of the second clock signal; and the noise reduction circuitry outputs the third power supply signal to the pull-up node PU and the output terminal OUT respectively under the control of the pull-down node PD.

In the embodiment of the present disclosure, the potential of the first power supply signal may be the first potential, and the potentials of both the second power supply signal and the third power supply signal may be the second potential.

The driving method of the shift register according to the embodiment of the present disclosure further comprises the pre-reset period before the charging period. In the pre-reset period, the pre-reset circuitry may reset the pull-up node and the output terminal of each of the shift registers, so that the shift register which is turned on in error may be turned off in time, in order to avoid the white line being badly rendered at the bottom of the display panel due to the erroneous turn-on of the last stage of shift register, thus improving the output stability of the shift register and guaranteeing the display effect of the display device.

In an implementation of the embodiment of the present disclosure, the pre-reset circuitry 60 may comprise a first transistor M1 and a second transistor M2, with reference to FIG. 2.

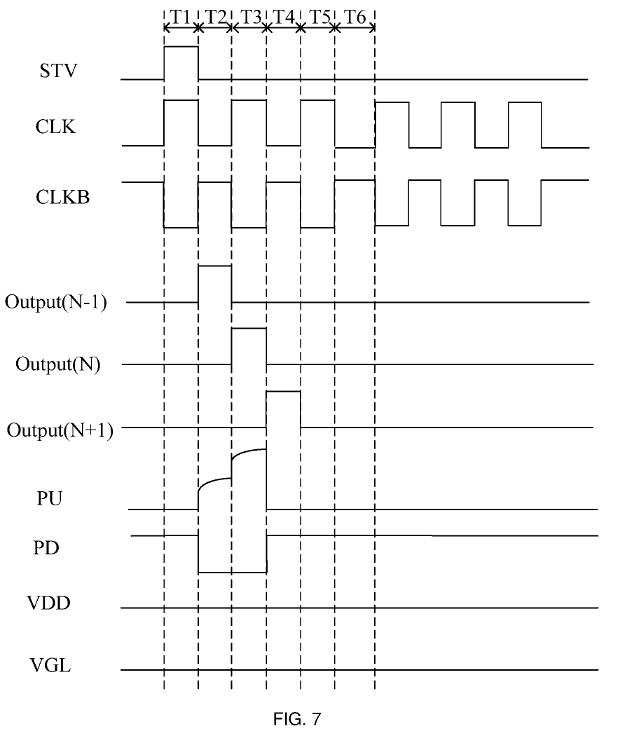

FIG. 7 shows a timing sequence diagram of a driving process of a shift register according to an embodiment of the present disclosure. With reference to FIG. 7, in the pre-reset period T1, the frame start signal input from the frame start signal terminal STV is at the first potential, so that the first transistor M1 and the second transistor M2 are turned on, the third power supply signal terminal VGL outputs the third power supply signal to the pull-up node PU and the output terminal OUT respectively, and a potential of the third power supply signal is the second potential, thereby implementing reset of the pull-up node PU and the output terminal OUT.

If there is a chaos timing signal in the frame start signal input from the frame start signal terminal STV before the pre-reset period T1, it will cause respective stages of shift registers to be sequentially turned on in error. When the start signal input from the frame start signal terminal STV becomes normal and inputs a frame start signal at the first potential, the pull-up nodes PU and the output terminals OUT in the respective shift registers may be reset in time, and the shift register(s) being turned on in error may be turned off in time, thereby effectively avoiding the problem of a large current or the white line being badly rendered at the bottom of the display panel due to the last stage of shift register being turned on for a long time.

In another implementation of the embodiment of the present disclosure, the pre-reset circuitry 60 may comprise a third transistor M3, a fourth transistor M4 and a fifth transistor M5, with reference to FIG. 3.

As shown in FIG. 7, in the pre-reset period T1, the frame start signal input from the frame start signal terminal STV is at the first potential, the third transistor M3 is turned on, and the frame start signal terminal STV outputs the frame start signal to the pull-down node PD, so that the potential of the pull-down node PD is pulled high, and at this time the fourth transistor M4 and the fifth transistor M5 are turned on, and the third power supply signal terminal VGL outputs the third signal to the pull-up node PU and the output terminal OUT respectively. Since the potential of the third power supply signal is the second potential, reset of the pull-up node PU and the output terminal OUT in the shift register may be implemented either.

The driving method of the shift register according to the embodiment of the present disclosure will be described in detail by taking the shift register in the forward scanning as shown in FIG. 2 as an example. With reference to FIG. 2, the pull-down circuitry 40 may comprise a sixth transistor M6, a seventh transistor M7, and a first capacitor C1. The charging circuitry 10 may comprise an eighth transistor M8. The reset circuitry 20 may comprise a ninth transistor M9. The pull-up circuitry 30 may comprise a tenth transistor M10 and a second capacitor C2. The noise reduction circuitry 50 may comprise an eleventh transistor M11 and a twelfth transistor M12.

Referring to FIG. 7, in the charging period T2, the input signal input from the input signal terminal Input is an output signal Output (N−1) of a previous stage of shift register. As seen from FIG. 7, the output signal Output (N−1) of the previous stage of shift register in the charging period T2 is at the first potential, the input signal input from the input signal terminal Input is at the first potential, the eighth transistor M8 is turned on, the first power supply signal terminal VDD outputs the first power supply signal at the first potential to the pull-up node PU, so that the potential of the pull-up node PU is pulled high, thereby implementing charging of the pull-up node PU.

In the output period T3, the input signal jumps to the second potential, and the eighth transistor M8 is turned off. At this time, the first clock signal output from the first clock signal terminal CLK is at the first potential, and the second capacitor C2 causes the pull-up node PU to generate bootstrapping. The potential of the pull-up node PU is further pulled high. At this time, the tenth transistor M10 is turned on, and the first clock signal terminal CLK outputs the driving signal, i.e., the first clock signal, to the output terminal OUT.

The potential of the pull-up node PU is the first potential in the charging period T2 and the output period T3 as described above, so that the sixth transistor M6 is turned on, and the third power supply signal terminal VGL outputs the third power supply signal to the pull-down node PD via the sixth transistor M6, and the potential of the third power supply signal is the second potential. Therefore, in each of the two stages, both the eleventh transistor M11 and the twelfth transistor M12 are in a turn-off state, so as to prevent interference with the signal output from the output circuitry to the output terminal OUT, thereby guaranteeing the output stability of the shift register.

Further, in the reset period T4, the reset signal inputted from the reset signal terminal RST is an output signal Output (N+1) of a next stage of shift register. As can be seen from FIG. 7, the output signal Output (N+1) of the next stage of shift register in the reset period T4 is at the first potential, and at this time the ninth transistor M9 is turned on, the second power supply signal terminal VSS outputs the second power supply signal to the pull node PU, and the second power supply signal is at the second potential, thereby implementing reset of the pull-up node PU.

At the same time, in the reset period T4, the second clock signal output from the second clock signal terminal CLKB is at the first potential, the seventh transistor M7 is turned on, and the second clock signal terminal CLKB can output the second clock signal to the pull-down node PD, charging the first capacitor C1. Since the pull-down node PD is at the first potential, the eleventh transistor M11 and the twelfth transistor M12 are turned on, and the third power supply signal terminal VGL can output the third power supply signal to the pull-up node PU and the output terminal OUT respectively, thereby implementing reset of the pull-up node PU and output OUT.

In the noise reduction period T5, since the first capacitor C1 stores the first potential in the reset period T4, the pull-down node PD may continue to keep at the first potential in the noise reduction period T5. At this time, the eleventh transistor M11 and the twelfth transistor M12 in the noise reduction circuitry 50 are still kept in a turn-on state, and may continue to perform the noise reduction on the pull-up node PU and the output terminal OUT.

Referring to FIG. 7, after the noise reduction period T5, there may be a sixth period T6. In the sixth period T6, the second clock signal output from the second clock signal terminal CLKB is at the first potential, the seventh transistor M7 is turned on, and the second clock signal terminal CLKB charges the first capacitor C1 so that the pull-down node PD is kept at the first potential. The eleventh transistor M11 and the twelfth transistor M12 remain in the turn-on state, and continue to perform the noise reduction on the pull-up node PU and the output terminal OUT. After the sixth period T6 is ended, the shift register may repeat the noise reduction period T5 and the sixth period T6 until the next frame scanning is started, i.e., the noise reduction is continuously performed on the pull-up node and the output terminal, effectively improving a problem of a coupling noise voltage caused by the first clock signal terminal CLK, increasing a product yield and reducing an overall power consumption of the shift register.

At the start of the next frame scanning, the frame start signal STV is firstly triggered to be at the first potential, and the pre-reset circuitry in each of the shift registers is able to reset the pull-up node PU and the output terminal OUT. If, at this time, some shift register is in an erroneous turn-on state, the shift register which is turned on in error can be turned off in time, in order to guarantee the stability of the output.

It should be noted that in FIG. 7, Output (N) is a signal output from the output terminal of the shift register in each of respective embodiments as described above, and Output (N−1) is a signal output from a stage of shift register previous to the shift register, and Output (N+1) is a signal output from a stage of shift register next to the shift register.

The driving method of the shift register according to the embodiment of the present disclosure may implement bidirectional scanning of the shift register, in which when the backward scanning is being performed, the structure of the shift register may not be changed, except that functions of the input signal terminal, the reset signal terminal, the first power supply signal terminal and the second power supply signal terminal are changed, so that the functions of the eighth transistor M8 in the charging circuitry and the ninth transistor M9 in the reset circuitry are reversed. The principle of the backward scanning is the same as that of the forward scanning, a particular implementation process of which may refer to the above-mentioned implementation process of the forward scanning, and thus description thereof will not be described in the embodiment of the present disclosure again.

Respective embodiments as described above assume that the first to the twelfth transistors are N-type transistors, and the first potential is a high potential and the second potential is a low potential. Of course, the first to the twelfth transistors may also use P-type transistors. When the first to the twelfth transistors use P-type transistors, the first potential is a low potential, the second potential is a high potential, and variations of the potentials of the respective signal terminals and the node may be opposite to the variations of the potentials as shown in FIG. 7 (i.e., a period difference between them is 180 degrees).

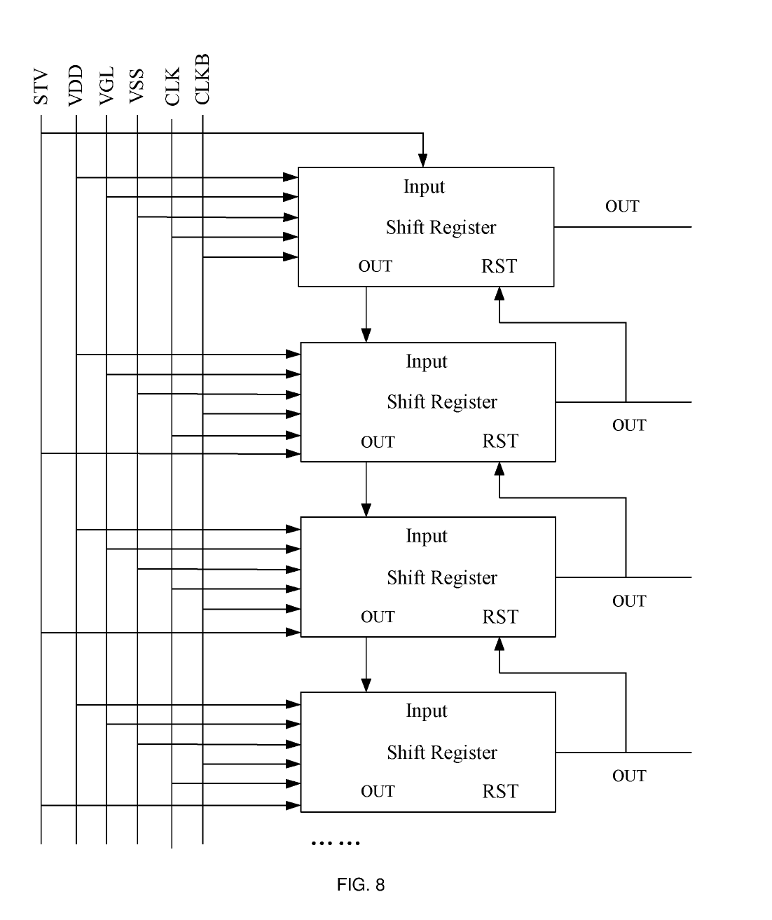

FIG. 8 shows a schematic structure diagram of a gate driving circuit according to an embodiment of the present disclosure. As shown in FIG. 8, the gate driving circuit may comprise at least two cascaded shift registers, each of which may be the shift register according to the embodiments of the present disclosure.

In addition, an embodiment of the present disclosure further provides a display device. The display device may comprise the gate driving circuit according to the embodiment of the present disclosure. The display device may be a liquid crystal panel, e-paper, an OLED (Organic Light Emitting Display) panel, an AMOLED (Active-Matrix Organic Light Emitting Display) panel, a mobile phone, a tablet, a television, a monitor, a laptop, a digital photo frame, a navigators, and any other display product or component having a display function.

The foregoing is only preferred ones of the embodiments of the present disclosure and is not intended to limit the embodiments of the present disclosure. Any modifications, equivalent substitutions, improvements, etc. made within the spirit and principles of the embodiments of the present disclosure fall into the protection scope of the embodiments of the present disclosure.

I/We claim:

1. A shift register, comprising:
charging circuitry coupled to an input signal terminal, a first power supply signal terminal and a pull-up node, configured for charging the pull-up node under control of an input signal from the input signal terminal;
reset circuitry coupled to a reset signal terminal, a second power supply signal terminal and the pull-up node, configured for resetting a potential of the pull-up node under control of a reset signal from the reset signal terminal;
pull-up circuitry coupled to a first clock signal terminal, the pull-up node and an output terminal respectively, configured for outputting a driving signal to the output terminal under control of the pull-up node;
pull-down circuitry coupled to the pull-up node, a pull-down node, a third power supply signal terminal and a second clock signal terminal, configured for controlling a potential of the pull-down node under control of the pull-up node and a second clock signal from the second clock signal terminal;
noise reduction circuitry coupled to the pull-down node, the third power supply signal terminal, the pull-up node and the output terminal, configured for performing noise reduction on the pull-up node and the output terminal under control of the pull-down node; and
pre-reset circuitry coupled to a frame start signal terminal, the third power supply signal terminal, the pull-up node and the output terminal, configured for resetting the potential of the pull node and a potential of the output terminal under control of a frame start signal from the frame start signal terminal.

2. The shift register according to claim 1, wherein:
the pre-reset circuitry comprises a first transistor and a second transistor;
a gate of the first transistor is coupled to the frame start signal terminal, a first electrode of the first transistor is coupled to the third power supply signal terminal, and a second electrode of the first transistor is coupled to the pull-up node; and
a gate of the second transistor is coupled to the frame start signal terminal, a first electrode of the second transistor is coupled to the third power supply signal terminal, and a second electrode of the second transistor is coupled to the output terminal.

3. The shift register according to claim 1, wherein:
the pre-reset circuitry comprises a third transistor, a fourth transistor and a fifth transistor;
a gate and a first electrode of the third transistor are coupled to the frame start signal terminal, and a second electrode of the third transistor is coupled to the pull-down node;
a gate of the fourth transistor is coupled to the pull-down node, a first electrode of the fourth transistor is coupled to the third power supply signal terminal, and a second electrode of the fourth transistor is coupled to the output terminal; and
a gate of the fifth transistor is coupled to the pull-down node, a first electrode of the fifth transistor is coupled to the third power supply signal terminal, and a second electrode of the fifth transistor is coupled to the pull-up node.

4. The shift register according to claim 1, wherein:
the pull-down circuitry comprises a sixth transistor, a seventh transistor and a first capacitor;
a gate of the sixth transistor is coupled to the pull-up node, a first electrode of the sixth transistor is coupled to the third power supply signal terminal, and a second electrode of the sixth transistor is coupled to the pull-down node;
a gate and a first electrode of the seventh transistor are coupled to the second clock signal terminal, and a second electrode of the seventh transistor is coupled to the pull-down node; and
a first terminal of the first capacitor is coupled to the pull-down node, and a second terminal of the first capacitor is coupled to the third power supply signal terminal.

5. The shift register according to claim 1, wherein the charging circuitry comprises an eighth transistor, and the reset circuitry comprises a ninth transistor, and
wherein when forward scanning is being performed, a gate of the eighth transistor is coupled to the input signal terminal, a first electrode of the eighth transistor is coupled to the first power supply signal terminal, and a second electrode of the eighth transistor is coupled to the pull-up node; a gate of the ninth transistor is coupled to the reset signal terminal, a first electrode of the ninth transistor is coupled to the second power supply signal terminal, and a second electrode of the ninth transistor is coupled to the pull-up node.

6. The shift register according to claim 1, wherein the charging circuitry comprises a ninth transistor, and the reset circuitry comprises an eighth transistor, and
wherein when backward scanning is being performed, a gate of the ninth transistor is coupled to the input signal terminal, a first electrode of the ninth transistor is coupled to the first power supply signal terminal, and a second electrode of the ninth transistor is coupled to the pull-up node; and a gate of the eighth transistor is coupled to the reset signal terminal, a first electrode of the eighth transistor is coupled to the second power supply signal terminal, and a second electrode of the eighth transistor is coupled to the pull-up node.

7. The shift register according to claim 1, wherein:
the pull-up circuitry comprises a tenth transistor and a second capacitor; and the noise reduction circuitry comprises an eleventh transistor and a twelfth transistor;
a gate of the tenth transistor is coupled to the pull-up node, a first electrode of the tenth transistor is coupled to the first clock signal terminal, and a second electrode of the tenth transistor is coupled to the output terminal;
one terminal of the second capacitor is coupled to the pull-up node, and the other terminal of the second capacitor is coupled to the output terminal;
a gate of the eleventh transistor is coupled to the pull-down node, a first electrode of the eleventh transistor is coupled to the third power supply signal terminal, and a second electrode of the eleventh transistor is coupled to the output terminal; and
a gate of the twelfth transistor is coupled to the pull-down node, a first electrode of the twelfth transistor is coupled to the third power supply signal terminal, and a second electrode of the twelfth transistor is coupled to the pull-up node.

8. The shift register according to claim 3, wherein the noise reduction circuitry comprises the fourth transistor and the fifth transistor.

9. The shift register according to claim 2, wherein each of the transistors is an N-type transistor.

10. A driving method of a shift register, wherein the shift register comprises charging circuitry, reset circuitry, pull-up circuitry, pull-down circuitry, noise reduction circuitry and pre-reset circuitry, the driving method comprising:
in a pre-reset period, outputting, by the pre-reset circuitry, a third power supply signal to the pull-up node and the output terminal respectively under control of a frame start signal;
in a charging period, outputting, by the charging circuitry, a first power supply signal to the pull-up node under control of an input signal;
in an outputting period, maintaining, by the pull-up node, a potential of the first power supply signal; and outputting, by the pull-up circuitry, a first clock signal to the output terminal under control of the pull-up node;
in a reset period, outputting, by the reset circuitry, a second power supply signal to the pull-up node under control of a reset signal; outputting, by the pull-down circuitry, a second clock signal to the pull-down node under control of the second clock signal; and outputting, by the noise reduction circuitry, the third power supply signal to the pull-up node and the output terminal respectively under control of the pull-down node; and
in a noise reduction period, maintaining, by the pull-down node, a potential of the second clock signal; and outputting, by the noise reduction circuitry, the third power supply signal to the pull-up node and the output terminal respectively under the control of the pull-down node.

11. The driving method according to claim 10, wherein the pre-reset circuitry comprises a first transistor and a second transistor; and
the method further comprises, in the pre-reset period, turning on the first transistor and the second transistor, outputting by the third power supply signal terminal, the third power supply signal to the pull-up node and the output terminal respectively, and a potential of the third power supply signal is a second potential and the frame start signal is at a first potential.

12. The driving method according to claim 10, wherein the pre-reset circuitry comprises a third transistor, a fourth transistor and a fifth transistor; and
the method further comprises, in the pre-reset period, turning on the third transistor, outputting by a frame start signal terminal, the frame start signal to the pull-down node, turning on the fourth transistor and the fifth transistor, outputting by the third power supply signal terminal, the third power supply signal to the pull-up node and the output terminal respectively, and a potential of the third power supply signal is a second potential and the frame start signal is at a first potential.

13. The driving method according to claim 10, wherein the pull-down circuitry comprises a sixth transistor, a seventh transistor and a first capacitor;
the method further comprises
in the charging period and the outputting period, turning on the sixth transistor, outputting by the third power supply signal terminal, the third power supply signal to the pull-down node, and a potential of the third power supply signal is a second potential and a potential of the pull-up node is a first potential;
in the reset period, turning on the seventh transistor, and outputting by the second clock signal terminal, the second clock signal to the pull-down node for charging the first capacitor and the second clock signal is at the first potential; and
in the noise reduction period, causing by the first capacitor, the pull-down node to maintain at a first potential.

14. The driving method according to claim 11, wherein each of the transistors is an N-type transistor, and the first potential is a high potential relative to the second potential.

15. A gate driving circuit, wherein the gate driving circuit comprises at least two cascaded shift registers according to claim 1.

16. A display device, comprising the gate driving circuit according to claim 15.

17. The method according to claim 12, wherein
each of the transistors is an N-type transistor, and the first potential is a high potential relative to the second potential.

18. The method according to claim 13, wherein
each of the transistors is an N-type transistor, and the first potential is a high potential relative to the second potential.

19. A gate driving circuit, wherein the gate driving circuit comprises at least two cascaded shift registers according to claim 2.

20. A gate driving circuit, wherein the gate driving circuit comprises at least two cascaded shift registers according to claim 3.
